(19) United States
(12) Patent Application Publication
(10) Pub. No.: US 2015/0262966 A1
(43) Pub. Date: Sep. 17, 2015

(54) METHOD AND APPARATUS FOR BONDING A SEMICONDUCTOR DEVICE OR COMPONENT TO A SUBSTRATE

(71) Applicant: DONG GUAN COWELL OPTIC ELECTRONICS LIMITED, Dongguan City (CN)

(72) Inventor: Sang Kyun LEE, Dongguan (CN)

(21) Appl. No.: 14/214,855

(22) Filed: Mar. 15, 2014

(51) Int. Cl. H01L 23/00

(52) U.S. Cl. CPC H01L 24/75

(57) ABSTRACT

An apparatus for bonding a semiconductor device or component such as a chip to a substrate comprises a heating device having a die where said die has a heating surface adapted to make thermal contact with an upper surface of said chip when said chip is placed with its lower surface over a substrate with a predetermined number of solder humps sandwiched between said lower surface and said substrate. The die is configured to heat the chip to cause the solder bumps to reflow. Once the reflowed solder bumps are set, the solder joint so thrilled is back-filled with a thermally setting epoxy paste. The heating surface of the die has a central region which contacts the upper surface of the chip and an outer region which extends beyond a peripheral edge of the upper surface of the chip. The die has a recess in its heating surface spanning said peripheral edge. The outer region of the die heating surface lies in a same or a lower plane than the die heating surface central region. The die comprises a planar heating member.

### FIELD OF THE INVENTION

The invention relates to a method and an apparatus for bonding semiconductor device or semiconductor component such as a chip or a chip carrier to a substrate such as a printed circuit board (PCB) or the like.

### BACKGROUND OF THE INVENTION

It is known to thermally bond chips to substrates such as PCBs using complementary arrays of reflow solder bumps on the chip and the substrate and to thereafter backfill the solder interface so formed with a thermally setting epoxy paste or the like.

A number of problems are encountered with such known methods including a failure to ensure proper wetting of the solder bumps across the whole of the array and a failure to prevent or reduce creep of the epoxy paste prior to it setting.

An object of the invention is to mitigate or obviate to some degree one or more problems associated with the known methods of bonding semiconductor devices or components to substrates.

### SUMMARY OF THE INVENTION

In a first main aspect, the invention provides an apparatus for bonding a semiconductor device or component to a substrate, comprising: a heating device having a die, said die having a heating surface adapted to make thermal contact with an upper surface of a semiconductor device or component when said semiconductor device or component is placed with its lower surface over a substrate with a predetermined number of solder bumps sandwiched between said lower surface and said substrate; said die being configured to heat the semiconductor device or component to cause said solder bumps to reflow; the heating surface of said die having a central region which contacts the upper surface of the semiconductor device or component and an outer region extending beyond a peripheral edge of the upper surface of the semiconductor device or component, the die having a recess in its heating surface spanning said peripheral edge of the upper surface of the semiconductor device or component.

In a second main aspect, the invention provides an apparatus for bonding a semiconductor device or component to a substrate, comprising: a heating device having a die, said die having a heating surface adapted to make thermal contact with an upper surface of a semiconductor device or component when said semiconductor device or component is placed with its lower surface over a substrate with a predetermined number of solder bumps sandwiched between said lower surface and said substrate; said die being configured to heat the semiconductor device or component to cause said solder bumps to reflow; the heating surface of said die having a central region which contacts the upper surface of the semiconductor device or component and an outer region extending, beyond peripheral edge of the upper surface of the semiconductor device or component, but lying in a same or lower plane than the die heating surface central region.

In a third main aspect, the invention provides an apparatus for bonding a semiconductor device or component to a substrate, comprising: a heating device having a die, said die having a heating surface adapted to make thermal contact with an upper surface of a semiconductor device or component when said semiconductor device or component is placed with its lower surface over a substrate with a predetermined number of solder bumps sandwiched between said lower surface and said substrate; said die being configured to heat the semiconductor device or component to cause said solder bumps to reflow; the heating surface of said die having, a central region which contacts the upper surface of the semiconductor device or component and an outer region extending beyond a peripheral edge of the upper surface of the semiconductor device or component, the die comprising a planar heating member.

In a fourth main aspect, the invention provides a method of bonding a semiconductor device or component to a substrate using solder bumps, comprising the steps of: providing a semiconductor device or component having an upper surface and a lower surface; placing said lower surface over said substrate with a predetermined number of solder bumps sandwiched between said lower surface and said substrate and applying a heating Surface of a die to an upper surface of said Semiconductor device or component to cause sad solder bumps to reflow; wherein said heating surface is applied to said upper surface such that a central region of the heating surface extends over said upper surface of the semiconductor device or component and said heating surface has an outer region extending beyond a peripheral edge of the upper surface of the semiconductor device or component, the die being provided with a recess in its heating surface, said recess spanning said peripheral edge of the upper surface of the semiconductor device or component.

In a fifth main aspect, the invention provides a method of bonding a semiconductor device or component to a substrate using solder bumps, comprising the steps of: providing a semiconductor device or component having an upper surface and a lower surface; placing said lower surface over said substrate with a predetermined number of solder bumps sandwiched between said lower surface and said substrate; and applying a heating surface of a die to an upper surface of said semiconductor device or component to cause said solder bumps to reflow; wherein a central region of the heating surface of the die extends over said upper surface of said semiconductor device or component and said heating surface further extends over an outer region beyond a peripheral edge of the tipper surface of the semiconductor device or component, but lying in a same or lower plane than the die heating surface central region.

In a sixth main aspect, the invention provides a method of bonding a semiconductor device or component to a substrate using solder bumps, composing the steps of providing a semiconductor device or component having an upper surface and a lower surface; placing said lower surface over said substrate with a predetermined number of solder bumps sandwiched between said lower surface and said substrate; and applying a heating, surface of a die to an upper surface of said semiconductor device or component to cause said solder bumps to reflow; wherein said heating surface is applied to said upper surface such that a central region of the heating surface extends over said upper surface of the semiconductor device or component and said heating surface has an outer region extending beyond a peripheral edge of the upper surface of the semiconductor device or component, the die comprising a planar heating member.

### BRIEF DESCRIPTION OF THE DRAWINGS

The foregoing and further features of the present invention will be apparent from the following description of preferred embodiments which are provided by way of example only in connection with the accompanying figures, of which:

FIG. 1 is a side view of a chip bonded to a substrate;

FIG. 2 is a plan view from above of FIG. 1;

FIG. 3 is a side view and a top plan view of a known apparatus for bonding a chip to a substrate;

FIG. 4 is a side view and a top plan view of another known apparatus for bonding a chip to a substrate;

FIG. 5 is a side view of the apparatus of FIG. 4 including a heating device;

FIG. 6 is a side view of the apparatus of FIG. 4 showing a first temperature distribution characteristic for the apparatus when bonding a chip to a substrate;

FIG. 7 is a side view of the apparatus of FIG. 4 showing a second temperature distribution characteristic tier the apparatus when bonding a chip to a substrate;

FIG. 8 is a side view and a top plan view of apparatus for bonding a chip to a substrate in accordance with the invention;

FIG. 9 is a side view of the apparatus of FIG. 8 including a heating device;

FIG. 10 is a side view of the apparatus of FIG. 8 showing a first temperature distribution characteristic for the apparatus when bonding a chip to a substrate; and

FIG. 11 is a side view of the apparatus of FIG. 8 showing a second temperature distribution characteristic for the apparatus when bonding a chip to a substrate.

### DESCRIPTION OF PREFERRED EMBODIMENTS

The following description is of preferred embodiments by way of example only and without limitation to the combination of features necessary for carrying the invention into effect.

In general, the invention relates to an apparatus for bonding a semiconductor device or component such as a chip to a substrate. The apparatus comprises a heating device having a die where said the has a heating surface adapted to make thermal contact with an upper surface of said chip when said chip is placed with its lower surface over a substrate with a predetermined number of solder bumps sandwiched between said lower surface and said substrate. The die is configured to heat the chip to cause the solder bumps to reflow. Once the reflowed solder bumps are set, the solder joint so formed may be back-filled with a thermally setting epoxy paste. The heating surface of the die has a central region which contacts the upper surface of the chip and an outer region which extends beyond a peripheral edge of the upper surface of the chip. The die may have a recess in its heating surface spanning said peripheral edge. The outer region of the die heating surface may lies in a same or a lower plane than the die heating surface central region. The die may comprise a planar heating member.

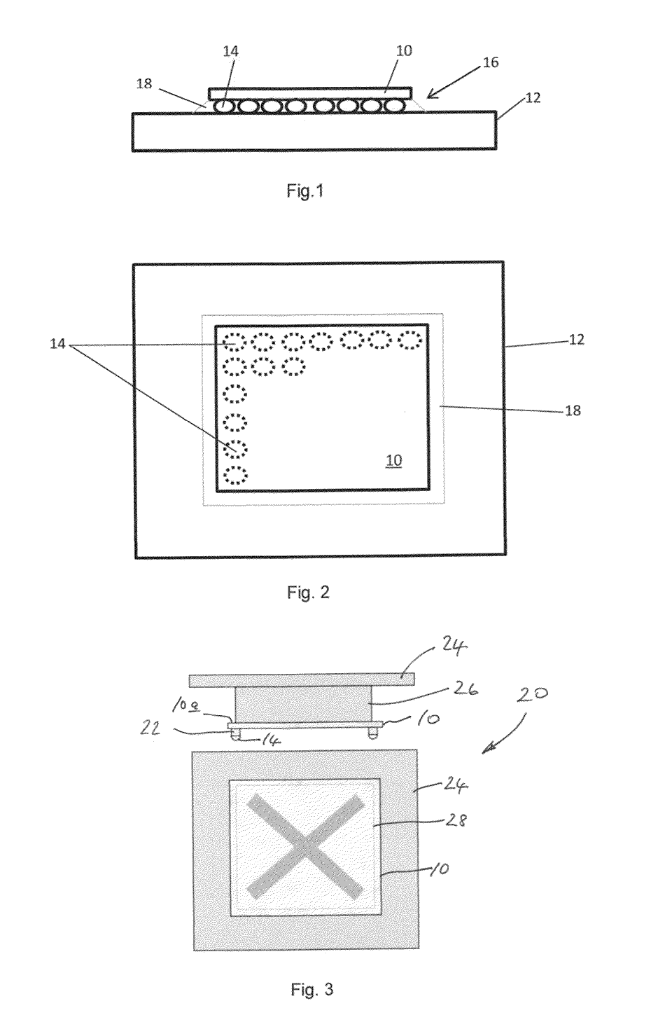

Referring to FIGS. 1 and 2, a chip 10 is bonded to a substrate 12 by a plurality of reflow solder bumps 14 to form a solder interface or joint 16. As will be familiar to a skilled artisan, each of the chip 10 and the substrate 12 is provided with a complementary array of solder bumps 14 as can be best seen in FIG. 2 although the array indicated by the array of dashed circular lines is not complete. The corresponding bumps 14 in each array are caused to reflow together when heat is applied to an upper surface of the chip 10 by known means thereby forming the solder interface 16, Once the solder interface 16 is formed, a bonding agent 18 such as a thermally setting epoxy based paste is backfilled into the solder interface 16. Heat applied to the top surface of the chip 10 causes the epoxy paste 18 to set to complete the bonding of the chip 10 to the substrate 12.

The reference herein to “chip” is to be taken to mean a processing chip such as a computer chip, a data processing chip or an information processing chip, it can also be taken to refer to a semiconductor device or even a semiconductor component such as a chip carrier or the like.

Referring to FIG. 3, shown is a known apparatus 20 for bonding a chip 10 to a substrate (not shown). The chip 10 is shown with solder bumps 14 provided on terminals 22 only at sides of the chip 10, but it will be understood that these are merely representative of an array of solder bumps 14 provided on a lower surface of the chip 10. The bonding apparatus 20 comprises a heating device (not shown) which sits above and provides thermal energy to a heating interface 24. Mounted below the heating interface 24 is a heating die 26 which may comprise a block of metal or any suitable thermally conductive material. The die 26, which is heated by the interface 24, is applied, in use, to an upper surface of the chip 10 to thereby cause reflow of the solder bumps 14 on both the chip 10 and the substrate 12. In this known apparatus 20, a heating surface of the die 26 which contacts the upper surface of the chip 10 has a width which is less than a width of the upper surface of the chip 10 as can be best seen in the plan view of FIG. 3. In the plan view of FIG. 3, the dashed line 28 represents the footprint of the contact of the die 26 on the upper surface of the chip 10.

With this known apparatus 20, a first problem arises in that peripheral edge regions 10a of the chip 10 have no direct heat applied thereto which commonly results in a failure of the solder bumps 14 at the edges of the solder bump arrays to reflow properly, i.e. to re-wet properly leading to poor quality solder connections between corresponding solder bumps 14 at the edges of the arrays. A further problem which may occur is that, due to poor heating at the peripheral edge regions 10a of the chip 10, the back-filled epoxy paste 18 may creep sideways by more than a desired amount before it sets thereby increasing the amount by which it is needed to separate chip bonding locations on the substrate 12.

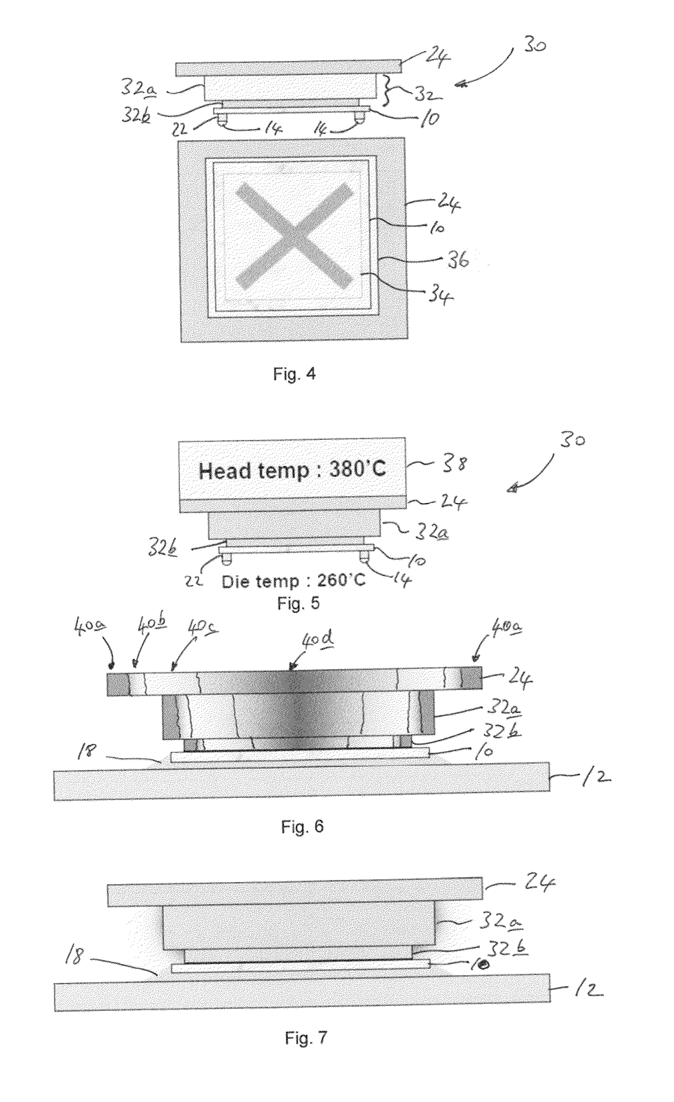

In an attempt to partially overcome some of the problems associated with the apparatus of FIG. 3, an improved bonding apparatus 30 as shown in FIG. 4 has been provided, but problems still persist even with the improved apparatus 30. in the apparatus 30 of FIG. 4, the die 32 has a stepped arrangement whereby a main body 32a of the die 32 is made wider than that of the die 26 of the apparatus 30 of FIG. 3, but where a contact part 32b of the die 32 is made to have a smaller size than the upper surface of the chip 10. As can best be seen in the plan view of FIG. 4, the footprint of the contact of the die 32 on the upper surface of the chip 10 as represented by dashed line 34 is the same as that for FIG. 3, but the main body 32a of the die 32, which does not directly contact the chip 10, is slightly larger in width and area than the upper surface of the chip as denoted by line 36 in the plan view of FIG. 4. As such, the main body 32a of the die 32 extends over the upper surface of the chip 10, but at a higher plane than the heating surface of the contact part 32b.

FIG. 5 shows the apparatus 30 with a heating device 38 for providing thermal energy to the heating interface 24 which, in turn, heats the stepped die 32.

As can be seen in FIG. 6, the thermal profile oldie heated interface 24 and the stepped die 32 is such that outer edge regions 40a of each of these components are cool with inner regions 40b, c, d delimited by the irregular lines in FIG. 6, being progressively hotter. This thermal pattern or characteristic is apparent through the interface 24, die main body part 32a and die contact part 32b. What is evident is that the problem of failure to properly re-wet solder bumps 14 at peripheral edge regions 10a of the chip persists as does the problem of sideways creeping of the epoxy paste before it sets.

FIG. 7 shows that heat intensity at the sides of the die 32 is relatively low due to the cooling of the outer edge regions of the heat interface 24 and the die 32.

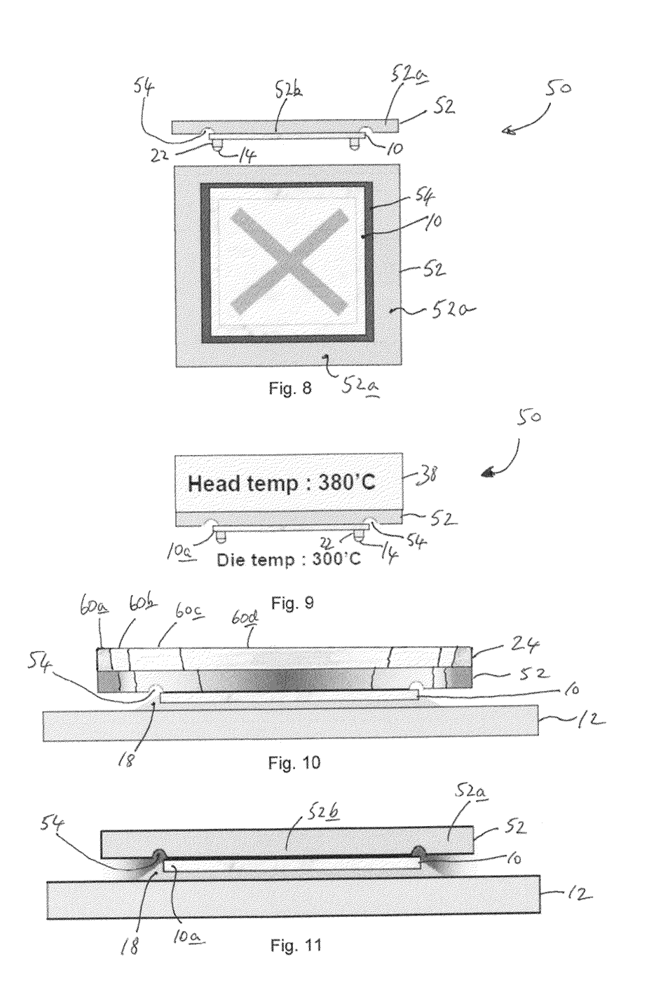

Referring now to FIGS. 8 to 11, shown is an improved bonding apparatus 50 according to the invention. In FIG. 8, only the die 52 of the apparatus 50 is shown. The heating device 38 and heating interface 24 are not shown. The heating interface 24 may not be required. These components of the apparatus 50 can he seen in FIG. 9. As will be apparent from at least FIG. 8, the die 52 preferably comprises a single, planar element formed to have a size which exceeds that of the upper surface of the chip 10. The size of the die 52 is preferably such that the die 52 has one or more outer regions or flanges 52a which extend beyond one or more peripheral edges 10a of the upper surface of the chip 10 and which preferably lie in a same plane as a central region 5b of the die which forms a part of a heating surface of the die 52. The central region 52b of the die 52 is that central part of the heating surface of the die 52 which makes direct contact with the upper surface of the chip 10. In some embodiments, the one or more outer regions 52a of the die may lie in a plane lower than that of the central region 52b to thereby be closer to the substrate 12.

The die 52 is preferably made to have a size which is substantially the same as that of the heating interface 24 or heater device 38 as is best seen in FIGS. 9 and 10. As shown in FIG. 9, one advantage of the improved apparatus 50 of the invention is that the die temperature remains consistently higher for a given temperature of the heating device 38 than in the known apparatuses 20, 30 of FIGS. 3 and 4.

FIG. 10 shows that a thermal profile of the heated interface 24 and the planar die 52 is such that outer edge regions 60a of each of these components remain hot with inner regions 60b, c, d, delimited by the irregular lines in FIG. 10, being progressively hotter. This thermal pattern or characteristic is apparent through the interface 24 and die 52. Consequently, as shown in FIG. 11, heat intensity at the sides of the die 52 is relatively high.

A number of advantages follow from the improved apparatus 50 of FIGS. 8 to 11. A first advantage is that the apparatus is more thermally efficient maintaining consistently higher temperatures than known apparatuses at the heating surface of the die 52 and thus at the upper surface of the chip 10. A further advantage is that the temperature profile across the upper surface of the chip 10 is more even, there not being cool edge regions at the outer regions 10a of the chip 10. Yet another advantage is a reduction in failure to properly re-wet solder bumps 14, particularly those positioned near the outer peripheral edges 10a of the chip. Yet another advantage is that the outer regions 52a of the die 52 which extend beyond the outer edges 10a of the chip in the same (or a lower) plane provide heat at said outer regions to more quickly and evenly set the back-filled epoxy paste 18 thereby reducing sideways creep of the paste 18. This can result in better density of chips on a substrate 12 as the chip locations can be brought closer together. Furthermore, the higher and more consistent temperature profile of the die 32 across its heating surface allows more efficient re-wetting, of solder bumps 14 such that chips with higher density arrays of solder bumps 14 can be bonded to the substrate 12 than is the case with the known apparatuses described herein. The solder bumps 14 are not shown in FIGS. 10 and 11 for reasons of clarity, but it will be understood that they remain part of the bonding structure.

By making the die 52 larger at its contact surface with the chip 10 than the chip upper surface can lead to the problem that bonding agent 18 may, before it sets, creep by means of capillary action into the small gap between the surface of the central region 52b of the die 52 and the upper surface of the chip 10. To address this issue, the die 52 preferably has a recess 54 in its heating, surface having an open width spanning said at least one peripheral edge 10a of the upper surface of the chip 10. The recess 54 which starts before the outer edge of the chip 10 and ends after that outer edge of the chip 10 prevents or reduces the ingress of epoxy paste into the gap before the paste 18 has set. The recess preferably has a width of between 300 micrometers to 500 micrometers, whilst the die preferably has a thickness of 500 micrometers or less, but preferably in the range from 300 to 450 micrometers. The recess 54 preferably overlaps the edge 10a of the chip by an amount in the range of 100 micrometers to 150 micrometers. It has been found that an overlap of at least 100 micrometers is sufficient to prevent creep of the epoxy pasts 18 into the gap. The recess 54 also has the further unexpected advantage of facilitating die centering and monitoring when the die is brought into contact with the chip 10.

The recess 54 is preferably semi-circular in cross-section, although it may take other cross-sectional shapes such as triangular or square.

The die 52 may be formed from a metal or a ceramic.

The heat bonding process of the invention may comprise a thermal compression non-conductive paste process.

1. An apparatus for bonding a semiconductor device or component to a substrate, comprising:
a heating device having a die, said die having a heating surface adapted to make thermal contact with an upper surface of a semiconductor device or component when said semiconductor device or component is placed with its lower surface over a substrate with a predetermined number of solder bumps sandwiched between said lower surface and said substrate; said die being configured to heat the semiconductor device or component to cause said solder bumps to reflow; the heating surface of said die having a central region which contacts the upper surface of the semiconductor device or component and an outer region extending beyond a peripheral edge of the upper surface of the semiconductor device or component, the die having a recess in its heating surface spanning said peripheral edge of the upper surface of the semiconductor device or component.

2. The apparatus of claim 1, wherein the die has a thickness of 500 micrometers or less.

3. The apparatus of claim 1, wherein the recess has a width of between 300 micrometers to 500 micrometers.

4. An apparatus for bonding a semiconductor device or component to a substrate, comprising:
a heating device having a die, said die having a heating surface adapted to make thermal contact with an upper surface of a semiconductor device or component when said semiconductor device or component is placed with its lower surface over a substrate with a predetermined number of solder bumps sandwiched between said lower surface and said substrate; said die being configured to heat the semiconductor device or component to cause said solder bumps to reflow; the heating surface of said die having a central region which contacts the upper surface of the semiconductor device or component and an outer region extending beyond a peripheral edge of the upper surface of the semiconductor device or component, but lying in a same or lower plane than the die heating surface central region.

5. The apparatus of claim 4, wherein the die has a thickness of 500 micrometers or less.

6. The apparatus of claim 4, wherein the recess has a width of between 300 micrometers to 500 micrometers.

7. An apparatus for bonding a semiconductor device or component: to a substrate, comprising:
a heating device having a die, said die having a heating surface adapted to make thermal contact with an upper surface of a semiconductor device or component when said semiconductor device or component is placed with its lower surface over a substrate with a predetermined number of solder bumps sandwiched between said lower surface and said substrate; said die being configured to heat the semiconductor device or component to cause said solder bumps to reflow; the heating surface of said die having a central region which contacts the upper surface of the semiconductor device or component and an outer region extending beyond a peripheral edge of the upper surface of the semiconductor device or component, the die comprising a planar heating member.

8. The apparatus of claim 7, wherein the die has a thickness of 500 micrometers or less.

9. The apparatus of claim 7, wherein the recess has a width of between 300 micrometers to 500 micrometers.
